(19) United States
(12) Patent Application Publication
(10) Pub. No.: US 2025/0291427 A1
(43) Pub. Date: Sep. 18, 2025

(54) KEY DEVICE

(71) Applicant: Chicony Electronics Co., Ltd., New Taipei City (TW)

(72) Inventors: Tao Kuan Chen, New Taipei City (TW); Huei Chen Wong, New Taipei City (TW)

(73) Assignee: Chicony Electronics Co., Ltd., New Taipei City (TW)

(21) Appl. No.: 18/755,696

(22) Filed: Jun. 27, 2024

(30) Foreign Application Priority Data
Mar. 13, 2024 (TW) 113109236

(51) Int. Cl. G06F 3/02; H03K 17/965

(52) U.S. Cl. CPC G06F 3/0202; H03K 17/965

(57) ABSTRACT

A key device includes a housing and a keycap module. The housing includes a side wall and a keyhole surrounded by the side wall. The side wall includes an upper stop surface. The keycap module includes a sliding plunger and a cap. The sliding plunger is movably disposed in the keyhole and includes a first limiting portion and a buffer component. The upper stop surface is located above the first limiting portion. The first limiting portion includes a top surface facing the cap and the upper stop surface and a bottom surface facing away from the cap. The buffer component protrudes from the top surface and the bottom surface, and a portion of the buffer component protruding from the top surface abuts the upper stop surface.

### CROSS-REFERENCE TO RELATED APPLICATION

This application claims the priority benefit of Taiwan application serial no. 113109236, filed on Mar. 13, 2024. The entirety of the above-mentioned patent application is hereby incorporated by reference herein and made a part of this specification.

### TECHNICAL FIELD

This disclosure relates to a key device, and in particular to a key device having a noise reduction function.

### DESCRIPTION OF RELATED ART

Currently, it is a prevalent input method for users to input information through keystrokes. The research direction in this field is to determine how to reduce the noise generated by the collision between elements during operation to improve the comfort of use.

### SUMMARY

This disclosure provides a key device that has a noise reduction function.

A key device of this disclosure includes a housing and a keycap module. The housing includes a side wall and a keyhole surrounded by the side wall. The side wall includes an upper stop surface. The keycap module includes a sliding plunger and a cap. The sliding plunger is movably disposed in the keyhole and includes a first limiting portion and a buffer component. The upper stop surface is located above the first limiting portion. The first limiting portion includes a top surface facing the cap and the upper stop surface and a bottom surface facing away from the cap. The buffer component protrudes from the top surface and the bottom surface. A portion of the buffer component protruding from the top surface is used to abut the upper stop surface.

In an embodiment of this disclosure, the sliding plunger and the cap are integrated.

In an embodiment of this disclosure, the cap is detachably disposed on the sliding plunger.

In an embodiment of this disclosure, the sliding plunger includes a first positioning portion. The cap includes a second positioning portion corresponding to the first positioning portion. One of the first positioning portion and the second positioning portion includes a convex portion extending along a first axial direction and a second axial direction perpendicular to each other, and other one includes a concave portion extending along the first axial direction and the second axial direction. The convex portion is detachably engaged with the concave portion.

In an embodiment of this disclosure, materials of the cap and the sliding plunger are different, and hardness of the buffer component is less than hardness of the materials of the cap and the sliding plunger.

In an embodiment of this disclosure, the buffer component penetrates the first limiting portion and protrudes from the top surface and the bottom surface.

In an embodiment of this disclosure, the buffer component and the first limiting portion are integrated.

In an embodiment of this disclosure, the buffer component and the first limiting portion are two separate pieces, and the buffer component is assembled to the first limiting portion.

In an embodiment of this disclosure, the side wall includes a lower stop surface, the sliding plunger includes a second limiting portion, and the lower stop surface is located below the second limiting portion to limit a downward movement range of the second limiting portion.

In an embodiment of this disclosure, the side wall includes an elastic arm, and the second limiting portion is a hook located on the elastic arm.

Based on the above, the sliding plunger of the keycap module of the key device of this disclosure is provided with the buffer component. The buffer component protrudes from the top surface and the bottom surface of the first limiting portion, which can effectively prevent the first limiting portion from directly impacting other elements when the keycap module is pressed to have a noise reduction function, thereby improving the comfort of use.

### BRIEF DESCRIPTION OF THE DRAWINGS

FIG. 1 is a schematic view of an appearance of a key device according to an embodiment of this disclosure.

FIG. 2 and FIG. 3 are schematic exploded views from different perspectives of the key device in FIG. 1.

FIG. 4 is a schematic cross-sectional view along a line segment A-A in FIG. 1.

FIG. 5 is a schematic exploded view of FIG. 4.

FIG. 6 is a schematic cross-sectional view along a line segment B-B in FIG. 1.

FIG. 7 is a schematic bottom view of a keycap module of the key device in FIG. 1.

FIG. 8 and FIG. 9 are schematic views from different perspectives of a keycap module of a key device moving upward according to another embodiment of this disclosure.

FIG. 10 is a schematic cross-sectional view of a key device according to another embodiment of this disclosure.

FIG. 11 and FIG. 12 are schematic views from different perspectives of a sliding plunger of the key device in FIG. 10.

FIG. 13 is a schematic exploded view of the sliding plunger in FIG. 11.

FIG. 14 is a schematic cross-sectional view of a key device according to another embodiment of this disclosure.

FIG. 15 and FIG. 16 are schematic views from different perspectives of a keycap module of the key device in FIG. 14.

### DETAILED DESCRIPTION OF DISCLOSED EMBODIMENTS

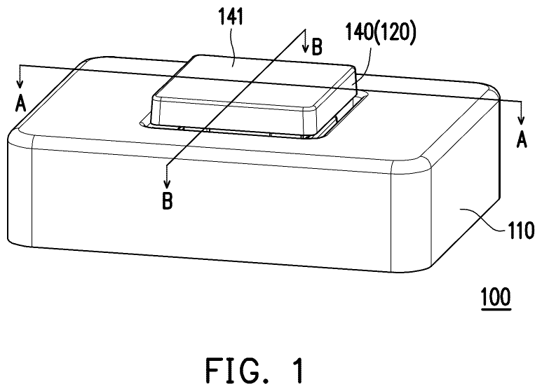

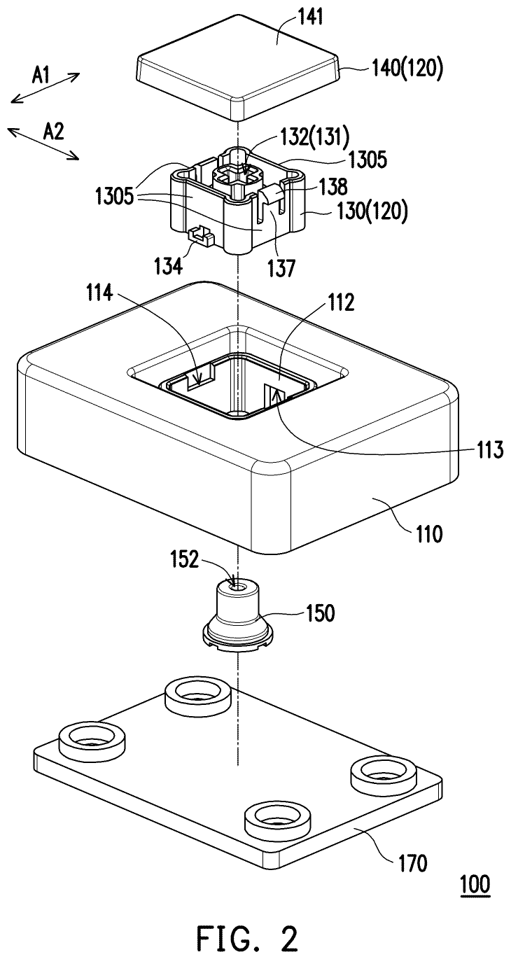

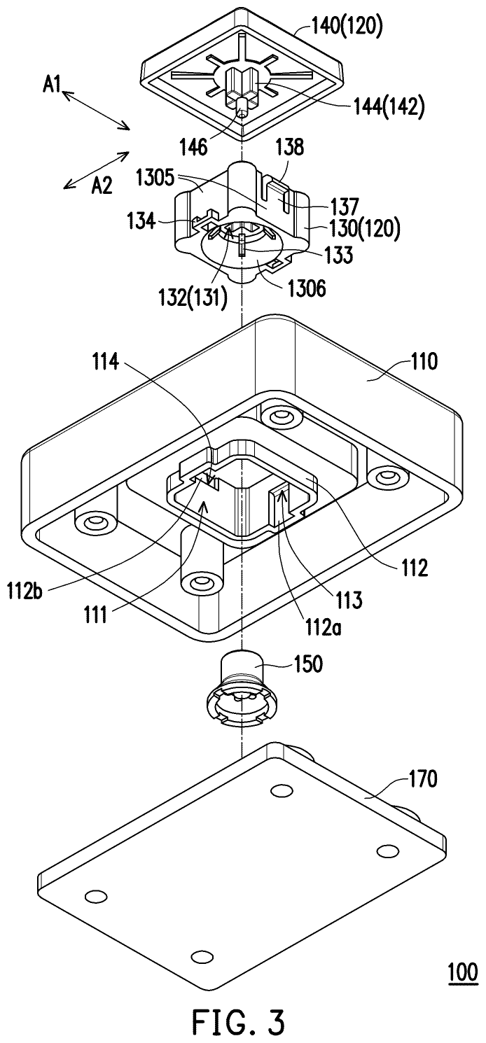

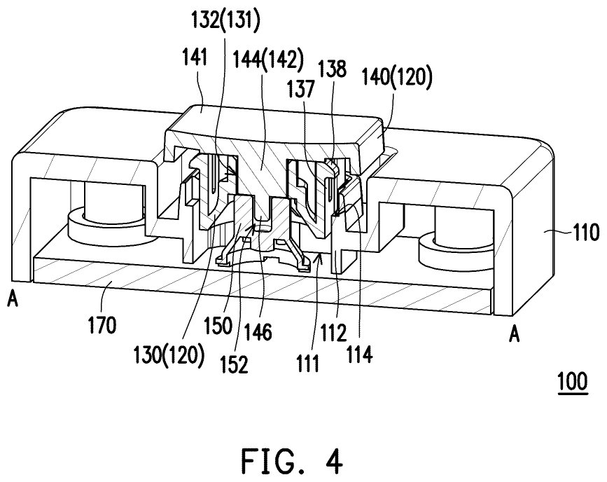

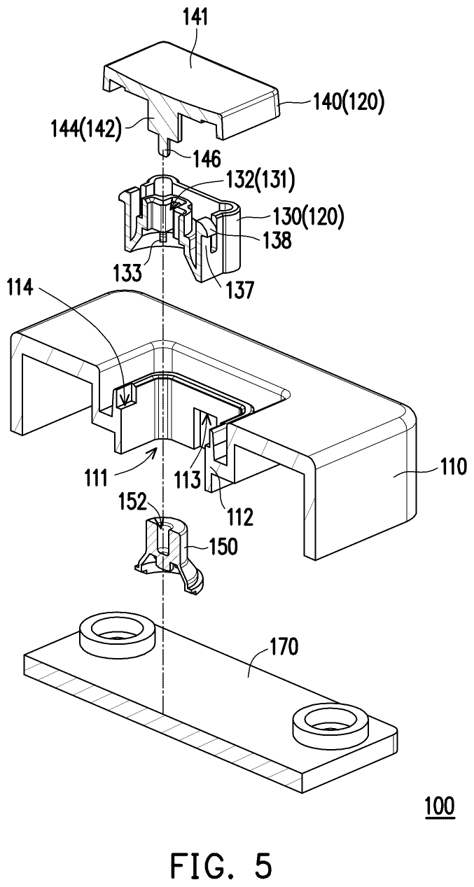

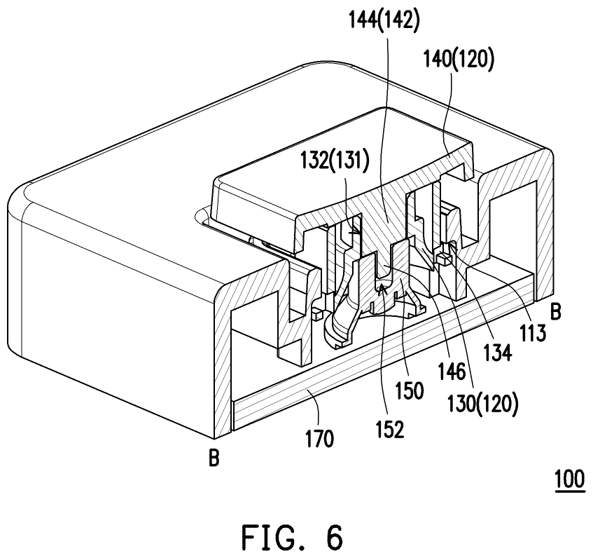

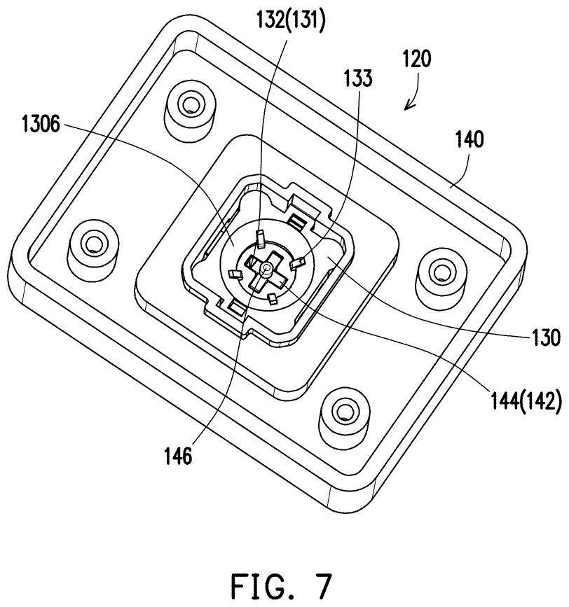

FIG. 1 is a schematic view of an appearance of a key device according to an embodiment of this disclosure. FIG. 2 and FIG. 3 are schematic exploded views from different perspectives of the key device in FIG. 1. FIG. 4 is a schematic cross-sectional view along a line segment A-A in FIG. 1. FIG. 5 is a schematic exploded view of FIG. 4. FIG. 6 is a schematic cross-sectional view along a line segment B-B in FIG. 1. FIG. 7 is a schematic bottom view of a keycap module of the key device in FIG. 1.

Please refer to FIG. 1 to FIG. 7. A key device 100 of this embodiment includes a housing 110 and a keycap module 120. As shown in FIG. 2 and FIG. 3, the housing 110 includes a side wall 112 and a keyhole 111 surrounded by the side wall 112. In this embodiment, the housing 110 takes a housing with a single key as an example. The side wall 112 is, for example, an annular inner wall inside the housing 110 that surrounds the keyhole 111. However, the position of the side wall 112 is not limited thereto. In other embodiments, the key device 100 may also be a keyboard, so that the housing 110 has multiple keyholes 111 and corresponding side walls 112.

The keycap module 120 includes a sliding plunger 130 and a cap 140. The sliding plunger 130 and the cap 140 may be combined into a unit that moves together. The sliding plunger 130 is movably disposed in the keyhole 111 and includes a first positioning portion 131. The cap 140 includes a second positioning portion 142 corresponding to the first positioning portion 131. In this embodiment, the second positioning portion 142 protrudes from the center of a bottom surface of the cap 140. The first positioning portion 131 is located at the center of the sliding plunger 130 and is disposed facing the cap 140. The cap 140 is detachably disposed on the first positioning portion 131 of the sliding plunger 130 through the second positioning portion 142.

Since the cap 140 of the key device 100 of this embodiment is detachable, the cap 140 is very convenient to replace. If the cap 140 is worn or the user has a preferred cap 140, the user may replace the cap 140 by himself from the front of the key device 100 without disassembling the entire key device 100. In addition, since the cap 140 may be well installed on the sliding plunger 130 through the alignment cooperation between the first positioning portion 131 and the second positioning portion 142, a stable pressing sensation can be provided.

It is worth mentioning that in this embodiment, since the cap 140 of the key device 100 is detachable, the cap 140 may be shared with other key devices. The forms of the other key devices are not limited to the key device 100 shown in FIG. 1, as long as the other key devices have the first positioning portion 131 that can cooperate with the second positioning portion 142 of the cap 140. Therefore, if multiple different types of key devices are produced, the same cap 140 may be used to save mold costs.

In addition, since the sliding plunger 130 and the cap 140 of the key device of this embodiment 100 are two separate pieces, the two may be made of different materials. Specifically, the sliding plunger 130 may be made of a self-lubricating material to reduce friction generated during sliding. The material of the sliding plunger 130 is, for example, polyoxymethylene (plastic steel, POM), rubber, or silicone. Of course, the material of the sliding plunger 130 is not limited thereto.

In addition, since the sliding plunger 130 and the cap 140 are two separate pieces, the two may be produced separately and then assembled during production. Therefore, the size of the sliding plunger 130 may not be limited by the mold manufacturing process. The size of the sliding plunger 130 may be increased as much as possible without affecting smooth sliding to be close to the size of the keyhole 111 to facilitate the stability of the keycap module 120 during the movement process, thereby improving the input pressing sensation for the user and efficacy.

As shown in FIG. 2, in this embodiment, the sliding plunger 130 includes multiple outer walls 1305, and the first positioning portion 131 is located between the outer walls 1305. The number of the outer walls 1305 is, for example, four. Outer contours of the outer walls 1305 generally present a square shape corresponding to the cap 140 and are connected in arcs at four corners. However, the outer contour of the sliding plunger 130 is not limited thereto.

As shown in FIG. 2 and FIG. 3, the size of the sliding plunger 130 is quite close to the size of the keyhole 111, and the size of the sliding plunger 130 is slightly smaller than the size of the cap 140. Such a design allows the larger sliding plunger 130 to still support the cap 140 well even if the four corners instead of the center of the cap 140 is pressed, so that the cap 140 may still move straight up and down, reducing the probability of shaking. Therefore, the stability of the cap 140 when pressed can be greatly improved, thereby ensuring good input effects.

In this embodiment, a range surrounded by a projection of the sliding plunger 130 on a cap top surface 141 of the cap 140 is greater than 70% of the size of the cap top surface 141. Of course, the size relationship between the sliding plunger 130 and the cap 140 is not limited thereto.

In addition, as shown in FIG. 2, in this embodiment, one of the first positioning portion 131 and the second positioning portion 142 includes a convex portion 144 extending along a first axial direction A1 and a second axial direction A2 perpendicular to each other, and the other one includes a concave portion 132 extending along the first axial direction A1 and the second axial direction A2. The convex portion 144 is detachably engaged with the concave portion 132.

Specifically, in this embodiment, the first positioning portion 131 is a cross-shaped hole, and the second positioning portion 142 is a cross-shaped protruding pillar. The first positioning portion 131 and the second positioning portion 142 may be well positioned to each other through the design mentioned above. Of course, in other embodiments, the first positioning portion 131 and the second positioning portion 142 may also be in other shapes, such as triangles, trapezoids, irregular shapes, etc. The shapes of the first positioning portion 131 and the second positioning portion 142 are not limited thereto.

In addition, in this embodiment, the first positioning portion 131 and the second positioning portion 142 may be tightly combined through tight fitting to prevent the cap 140 from being easily detached. Of course, the first positioning portion 131 and the second positioning portion 142 may also be combined through other manners, such as engagement, but are not limited thereto.

In this embodiment, the key device 100 further includes an elastic body 150 and a base plate component 170. The elastic body 150 is located in the keyhole 111, and the elastic body 150 is located above the base plate component 170 and below the sliding plunger 130 to abut against the sliding plunger 130. The elastic body 150 is, for example, a rubber structure. The elastic body 150 is used to lift the cap 140 and the sliding plunger 130 that are pressed and moved downward. The base plate component 170 includes, for example, a bracket and a circuit thin film. The base plate component 170 is only schematically illustrated, and the form of the base plate component 170 is not limited thereto.

As shown in FIG. 4, the cap 140 includes a third positioning portion 146, and the elastic body 150 includes a fourth positioning portion 152 corresponding to the third positioning portion 146. The third positioning portion 146 and the fourth positioning portion 152 are engaged with each other to fix the relative positions of the elastic body 150 and the cap 140.

Such a design can ensure that the elastic body 150 corresponds to the center of the cap 140 to prevent the center of the cap 140 and the center of the elastic body 150 from shifting due to vibrations during assembly or transportation. Such a design can also ensure that the feedback sensations for the user when pressing will not be different when pressing the four corners of the cap 140.

In this embodiment, the third positioning portion 146 is, for example, a pillar, and the fourth positioning portion 152 is, for example, a hole, but are not limited thereto. Specifically, in this embodiment, the third positioning portion 146 extends from the second positioning portion 142 toward the direction of the base plate component 170. The shape of the third positioning portion 146 is, for example, a circular pillar, and the shape of the fourth positioning portion 152 is, for example, a circular hole. However, in other embodiments, the third positioning portion 146 and the fourth positioning portion 152 may also be in other shapes, such as polygons, etc., for more accurate alignment. In addition, the third positioning portion 146 and the fourth positioning portion 152 may be tightly combined through tight fitting. Of course, the third positioning portion 146 and the fourth positioning portion 152 may also be combined through other manners, such as engagement, but are not limited thereto.

In addition, as shown in FIG. 3, the sliding plunger 130 has an inner conical surface 1306 connected to the outer walls 1305, and the inner conical surface 1306 faces the elastic body 150. As shown in FIG. 7, the sliding plunger 130 includes multiple symmetrically distributed guiding ribs 133 located on a side wall of the inner conical surface 1306 of the sliding plunger 130. The guiding ribs 133 are, for example, strip-shaped, and the number is, for example, four, but the shape and the number of the guiding ribs 133 are not limited thereto. It can be seen from FIG. 5 that the guiding ribs 133 face the elastic body 150, and particularly an outer surface of the elastic body 150. Since the guiding ribs 133 protrude from the inner conical surface of the sliding plunger 130, during the assembly process of the elastic body 150 and the sliding plunger 130, the guiding ribs 133 first contacts the outer surface of the elastic body 150, so that the elastic body 150 may be guided by the guiding ribs 133 to the center of the sliding plunger 130 to achieve automatic guidance. In other embodiments, the guiding ribs may also be disposed on the outer surface of the elastic body 150 or may be disposed at other positions of the sliding plunger 130 to guide the assembly of the elastic body 150.

As shown in FIG. 3 and FIG. 6, the side wall 112 of the housing 110 includes an upper stop surface 113. Specifically, the side wall 112 is provided with first guiding grooves 112a (FIG. 3) on two opposite sides. The first guiding grooves 112a are communicated with a bottom surface of the housing 110, and the first guiding groove 112a has the upper stop surface 113. The sliding plunger 130 includes a first limiting portion 134 formed on one of the outer walls 1305. The first limiting portion 134 is a square protruding block corresponding to the width of the first guiding grooves 112a. The first limiting portion 134 is slidably disposed in the first guiding groove 112a, and the upper stop surface 113 is located above the first limiting portion 134 to limit the upward movement range of the first limiting portion 134.

As shown in FIG. 3 and FIG. 4, the side wall 112 also includes a lower stop surface 114. The side wall 112 is provided with second guiding grooves 112b (FIG. 3) on two other sides other than the two sides provided with the first guide grooves 112a. The second guiding grooves 112b are communicated with a top surface of the housing 110, and the second guiding groove 112b has the lower stop surface 114. The sliding plunger 130 includes a second limiting portion 138 formed on another outer wall 1305. The second limiting portion 138 is, for example, a hook corresponding to the width of the second guiding groove 112b. The second limiting portion 138 is slidably disposed in the second guiding groove 112b, and the lower stop surface 114 is located below the second limiting portion 138 to limit the downward movement range of the second limiting portion 138.

Therefore, the sliding plunger 130 may slide between the upper stop surface 113 and the lower stop surface 114 of the housing 110. In this embodiment, the side wall 112 includes an elastic arm 137, and the second limiting portion 138 is a hook located on the elastic arm 137, so that the second limiting portion 138 can deflect and reset along with the elastic arm 137 during installation to facilitate assembly and positioning. Of course, the form of the second limiting portion 138 is not limited thereto.

Other forms of key devices 100′, 100a, and 100b are introduced below, and only the main differences are explained. The remaining identical or similar elements will not be described in detail.

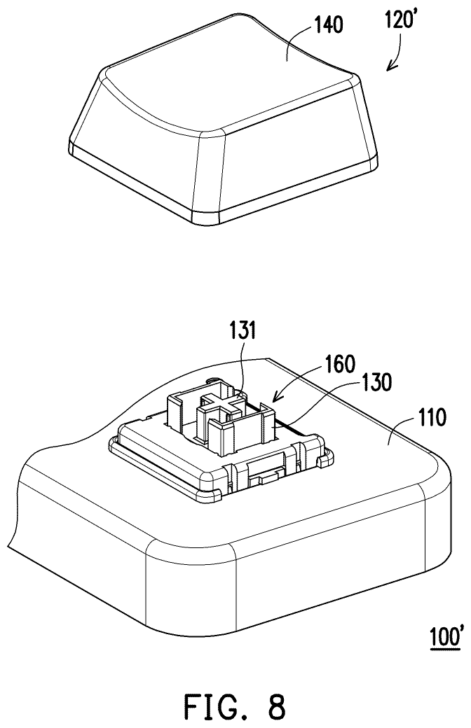

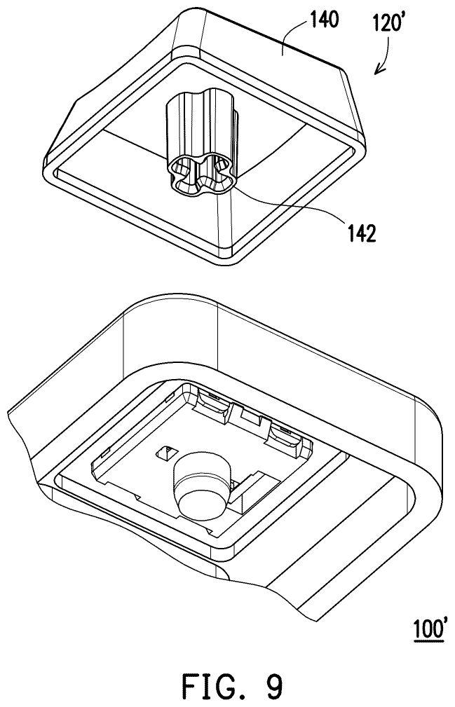

FIG. 8 and FIG. 9 are schematic views from different perspectives of a keycap module of a key device moving upward according to another embodiment of this disclosure. Please refer to FIG. 8 and FIG. 9. The main difference between the key device 100′ of this embodiment and the key device 100 of FIG. 1 is that in this embodiment, the key device 100′ is a mechanical key, the key device 100′ further includes a mechanical switch 160, and the mechanical switch 160 includes the sliding plunger 130. In other words, the type of the key device in this disclosure may be the key device 100 with the elastic body 150 or the key device 100′ with the mechanical switch 160.

Similarly, through the alignment cooperation between the second positioning portion 142 (FIG. 9) and the first positioning portion 131 (FIG. 8) of the sliding plunger 130, the cap 140 of a keycap module 120′ of this embodiment may be well fixed on the sliding plunger 130 of the mechanical switch 160 and can provide a stable pressing sensation. In addition, if the cap 140 is worn or the user has a preferred cap 140, the user may also replace the cap 140 by himself from the front of the key device 100′.

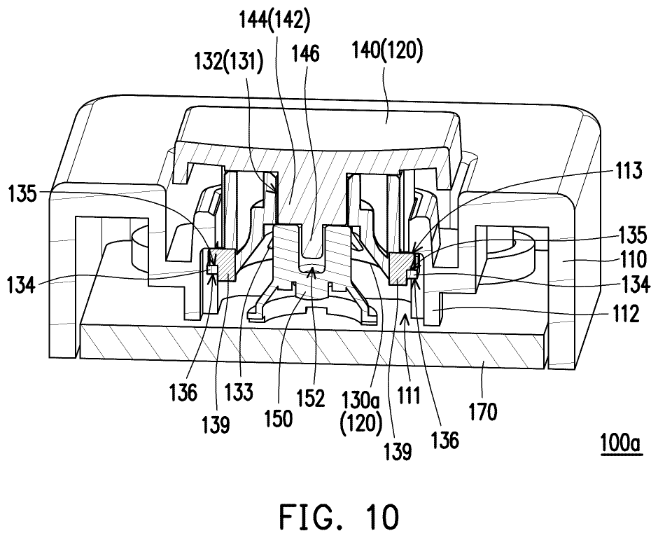

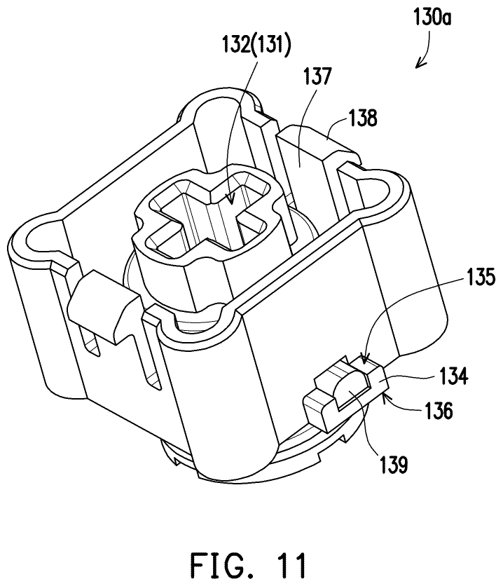

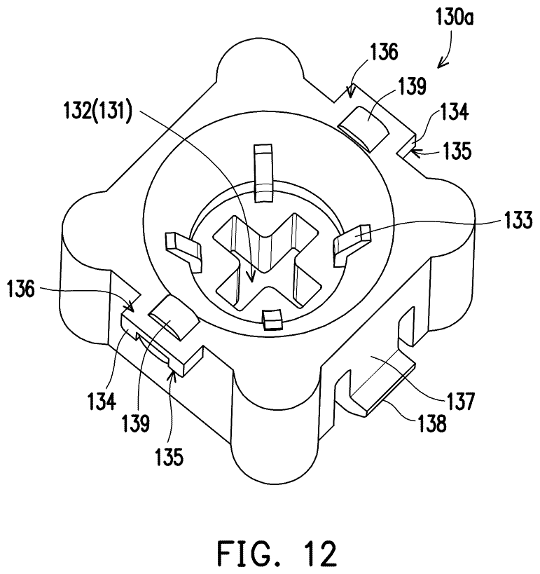

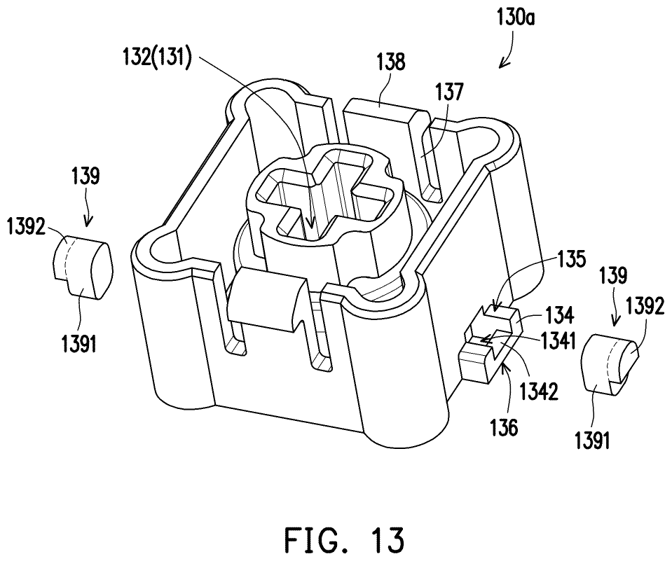

FIG. 10 is a schematic cross-sectional view of a key device according to another embodiment of this disclosure. FIG. 11 and FIG. 12 are schematic views from different perspectives of a sliding plunger of the key device in FIG. 10. FIG. 13 is a schematic exploded view of the sliding plunger in FIG. 11.

Please refer to FIG. 10 to FIG. 13. The main difference between the key device 100a of this embodiment and the key device 100 in FIG. 1 is that a sliding plunger 130a of this embodiment also includes a buffer component 139. Hardness of the buffer component 139 is less than hardness of the materials of the cap 140 and the sliding plunger 130a. In this embodiment, the buffer component 139 is, for example, rubber or silicone, but the type of the buffer component 139 is not limited thereto.

The first limiting portion 134 includes a top surface 135 facing the cap 140 and the upper stop surface 113 and a bottom surface 136 facing away from the cap 140. The buffer component 139 protrudes from the top surface 135 and the bottom surface 136 of the first limiting portion 134.

A portion of the buffer component 139 that protrudes from the bottom surface 136 is used to first contact the base plate component 170 when the cap 140 is pressed to prevent the first limiting portion 134 from directly impacting the base plate component 170 and generating loud noise. In addition, in an embodiment not shown, an annular buffer member may also be further added to a bottom portion of the sliding plunger 130a to reduce the probability of the sliding plunger 130a directly impacting the base plate component 170.

Similarly, a portion of the buffer component 139 that protrudes from the top surface 135 is used to abut the upper stop surface 113, and when the cap 140 rises after being pressed, the portion first contacts the upper stop surface 113 to prevent the first limiting portion 134 from directly impacting the upper stop surface 113 and generating loud noise.

As shown in FIG. 13, in this embodiment, the buffer component 139 and the first limiting portion 134 are two separate pieces, and the buffer component 139 is assembled to the first limiting portion 134. The buffer component 139 penetrates the first limiting portion 134 and protrudes from the top surface 135 and the bottom surface 136.

Specifically, the first limiting portion 134 includes a through hole 1341 and a recessed portion 1342. The recessed portion 1342 is located next to the through hole 1341. The recessed portion 1342 is recessed from the top surface 135 and is lower than the top surface 135. In this embodiment, the recessed portion 1342, for example, presents a concave space and platform lower than the top surface 135 and is used to carry and accommodate a partial local buffer component 139. Such a design can enable the buffer component 139 to be more stably and well disposed on the first limiting portion 134. Of course, in other embodiments, the first limiting portion 134 may also omit the design of the recessed portion 1342. The design is not limited by the drawings.

The through hole 1341 penetrates the top surface 135 and the bottom surface 136 of the first limiting portion 134. In addition, the buffer component 139 includes a first portion 1391 and a second portion 1392. The first portion 1391 is penetrated through the through hole 1341 and protrudes from the bottom surface 136, and the second portion 1392 is located on the recessed portion 1342 and protrudes from the top surface 135.

Such a design can increase the contact area between the buffer component 139 and the first limiting portion 134 to improve the stability of the buffer component 139. Of course, the forms of the first limiting portion 134 and the buffer component 139 are not limited thereto. In other embodiments, the buffer component 139 and the first limiting portion 134 may also be integrated, such as being manufactured through double injection. However, the relationship between the buffer component 139 and the first limiting portion 134 is not limited thereto.

In addition, in an embodiment, the portion protruding from the top surface 135 of the first limiting portion 134 and the portion protruding from the bottom surface 136 of the first limiting portion 134 in the buffer component 139 may be two separate pieces, each assembled to the first limiting portion 134 without being limited by the drawings.

It is worth mentioning that one of the current traditional noise reduction methods is to provide resistance through pre-pressuring the elastic body below the cap, so that when the user presses down the cap with normal force, the amount of downforce is not too great to prevent the structure below the cap from directly impacting the base plate component to reduce noise. However, if the elastic body is pre-pressed, when the user presses the cap, the sensation is blunt (that is, the sensation of more laborious pressing may occur), which may also cause the user to unconsciously increase the amount of pressing force, affecting the smoothness of use. The buffer component 139 of this embodiment is disposed on the first limiting portion 134, and the elastic body 150 does not need to be pre-pressed. Therefore, the user may press the keycap module 120 using normal force, and good noise reduction can be provided.

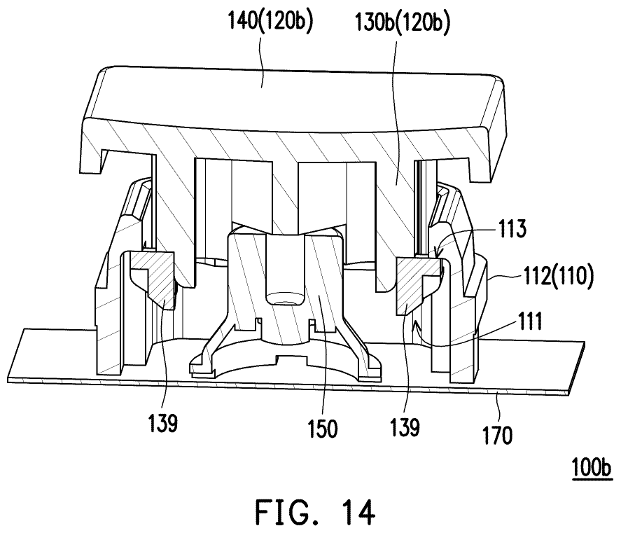

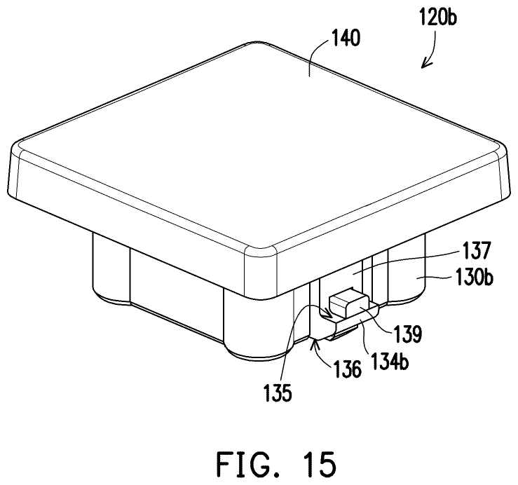

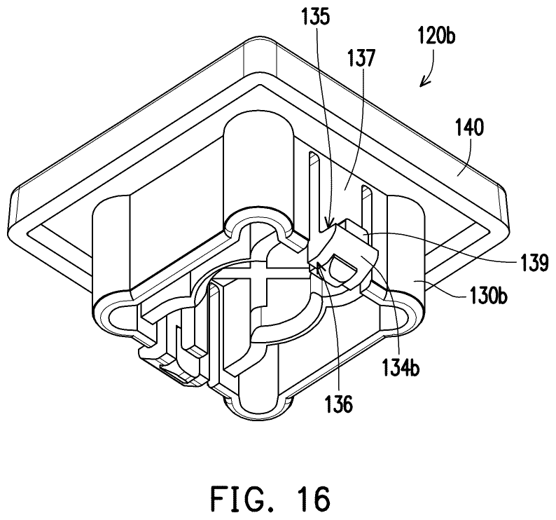

FIG. 14 is a schematic cross-sectional view of a key device according to another embodiment of this disclosure. FIG. 15 and FIG. 16 are schematic views from different perspectives of a keycap module of the key device in FIG. 14. Please refer to FIG. 14 to FIG. 16. The main difference between the key device 100b of this embodiment and the key device 100a in FIG. 10 is that a sliding plunger 130b and the cap 140 of the key device 100b are integrated. In addition, in this embodiment, a first limiting portion 134b is disposed on the elastic arm 137. Of course, the position of the first limiting portion 134b is not limited thereto.

Similarly, since the sliding plunger 130b of this embodiment includes the buffer component 139 protruding from the top surface 135 and the bottom surface 136 of the first limiting portion 134b, the noise generated by pressing down a keycap module 120b can be effectively reduced to provide a comfortable use quality.

To sum up, the sliding plunger of the key device of this disclosure is movably disposed in the keyhole of the housing, and the cap is detachably disposed in the first positioning portion of the sliding plunger through the second positioning portion to be fixed to the sliding plunger. The cap of the key device of this disclosure is detachable to facilitate replacement, and the cap can be well installed on the sliding plunger through the alignment cooperation between the first positioning portion and the second positioning portion to provide a stable pressing sensation. In addition, the sliding plunger of the keycap module of the key device of this disclosure is provided with the buffer component. The buffer component protrudes from the top surface and the bottom surface of the first limiting portion, which can effectively prevent the first limiting portion from directly impacting other elements when the keycap module is pressed to have a noise reduction function.

What is claimed is:

1. A key device, comprising:
a housing, comprising a side wall and a keyhole surrounded by the side wall, wherein the side wall comprises an upper stop surface; and
a keycap module, comprising a sliding plunger and a cap, wherein the sliding plunger is movably disposed in the keyhole and comprises a first limiting portion and a buffer component, the upper stop surface is located above the first limiting portion, the first limiting portion comprises a top surface facing the cap and the upper stop surface and a bottom surface facing away from the cap, the buffer component protrudes from the top surface and the bottom surface, and a portion of the buffer component protruding from the top surface is used to abut the upper stop surface.

2. The key device according to claim 1, wherein the sliding plunger and the cap are integrated.

3. The key device according to claim 1, wherein the cap is detachably disposed on the sliding plunger.

4. The key device according to claim 3, wherein the sliding plunger comprises a first positioning portion, the cap comprises a second positioning portion corresponding to the first positioning portion, one of the first positioning portion and the second positioning portion comprises a convex portion extending along a first axial direction and a second axial direction perpendicular to each other, other one of the first positioning portion and the second positioning portion comprises a concave portion extending along the first axial direction and the second axial direction, and the convex portion is detachably engaged with the concave portion.

5. The key device according to claim 3, wherein materials of the cap and the sliding plunger are different, and hardness of the buffer component is less than hardness of the materials of the cap and the sliding plunger.

6. The key device according to claim 1, wherein the buffer component penetrates the first limiting portion and protrudes from the top surface and the bottom surface.

7. The key device according to claim 1, wherein the buffer component and the first limiting portion are integrated.

8. The key device according to claim 1, wherein the buffer component and the first limiting portion are two separate pieces, and the buffer component is assembled to the first limiting portion.

9. The key device according to claim 1, wherein the side wall comprises a lower stop surface, the sliding plunger comprises a second limiting portion, and the lower stop surface is located below the second limiting portion to limit a downward movement range of the second limiting portion.

10. The key device according to claim 9, wherein the side wall comprises an elastic arm, and the second limiting portion is a hook located on the elastic arm.
